(19) United States
(12) Patent Application Publication
(10) Pub. No.: US 2010/0187552 A1
(43) Pub. Date: Jul. 29, 2010

(54) HYBRID WHITE ORGANIC LIGHT EMITTTNG DEVICE AND METHOD OF MANUFACTURING THE SAME

(75) Inventors: Jeong Ik Lee, Gyeonggi (KR); Hye Yong Chu, Daejeon (KR); Sung Mook Chung, Gyeonggi (KR); Lee Mi Do, Daejeon (KR); Sang Hee Park, Daejeon (KR); Chi Sun Hwang, Daejeon (KR)

Correspondence Address: AMPACC Law Group, 3500 188th Street S.W., Suite 103, Lynnwood, WA, 98037, US

(73) Assignee: Electronic and Telecommunications Research Institute, Daejeon (KR)

(21) Appl. No.: 12/664,040

(22) PCT Filed: Aug. 21, 2008
(86) PCT No.: PCT/KR2008/004869

§ 371 Date: Dec. 10, 2009

(30) Foreign Application Priority Data
Aug. 24, 2007 (KR) 10-2007-0085424
Jul. 8, 2008 (KR) 10-2008-0066177

(51) Int. Cl. H01L 51/52; H01L 51/56

(52) U.S. Cl. 257/98; 438/29; 257/E51.018

(57) ABSTRACT

Provided are a hybrid white organic light emitting diode (OLED) and a method of fabricating the same. A HOMO level difference between a fluorescent emission layer and an electron transport layer in an organic emission layer (OLED) becomes higher than that between the other layers or a LUMO level difference between a fluorescent emission layer and a hole transport layer is higher than that between the other layers, so that a recombination region is restricted to a part of an emission layer to obtain high-efficiency fluorescent light emission. In addition, triplet excitons that are not used in a fluorescent emission layer are transferred to an auxiliary emission layer formed to be spaced apart from a recombination region by a predetermined distance to emit light in a different color from the fluorescent emission layer, so that both singlet and triplet excitons formed in the OLED are used to obtain high-efficiency white light emission.

### TECHNICAL FIELD

The present invention relates to a hybrid white organic light emitting diode (OLED) and a method of fabricating the same, and more particularly, to a hybrid OLED and a method of fabricating the same, capable of increasing fluorescent emission efficiency by restricting a charge recombination region to a part of a fluorescent emission layer, and obtaining high-efficiency white light emission using singlet and triplet excitons generated in the fluorescent emission layer.

This work was supported by the IT R&D program of MIC/IITA [2005-S-070-03, Flexible Display].

### BACKGROUND ART

Recently, the development of a display industry has focused on high resolution as well as compactness in size, light weight and thin thickness using a thin film. To meet such a demand and implement a next generation display, an organic light emitting diode (OLED) technique among existing device manufacturing techniques has been drawing increasing attention, and research into the technique is actively progressing.

Generally, in an OLED, a first electrode, a hole transport layer, an emission layer, an electron transport layer, an insulating layer, and a second electrode are sequentially stacked under a high vacuum, and the first and second electrodes may be formed of a transparent electrode or a metal electrode. In the OLED, when a positive (+) electrode and a negative (−) electrode are respectively connected to the first electrode and the second electrode, holes from the first electrode are provided to the emission layer through the hole transport layer, and electrons from the second electrode are provided to the emission layer through the electron transport layer, so that they are combined in the emission layer to emit light. The OLED has a short response time, and is a self-emissive type that operates at a low supply voltage, so that it can be implemented in light weight and thin thickness since no back light is required. Also, the OLED exhibits excellent brightness, and has no view angle dependence.

Among methods of fabricating a display device using an OLED are a method of using a color filter to fabricate a full-color OLED, and a method of fabricating a white OLED that may be used as an LCD back light or a general use light.

In order to fabricate a white OLED having white light emitting characteristics, light emitting materials having light emitting characteristics of red (R), green (G) and blue (B) colors that are three primary colors of light may be stacked, or light emitting materials having a complementary color relationship (e.g., the combination of sky-blue and red or blue and orange). Accordingly, the white OLED may be classified as a three-wavelength white OLED or a two-wavelength white OLED.

Also, depending on a material used, the white OLED may be classified as a fluorescent white OLED or a phosphorescent white OLED. In the fluorescent white OLED, many materials having high stability have been developed for each color that is necessary to create white color, so that a very stable device may be fabricated. However, obstacles to an increase in efficiency resulting from not using triplet excitons generated in an OLED are on the rise. In the meantime, in the phosphorescent white OLED, many high efficiency materials are developed per color, so that a very high-efficiency white OLED can be fabricated. However, there is no blue phosphorescent material, and thus the device lacks stability.

Thus, to overcome the problems, a hybrid type device using both fluorescence and phosphorescence has been developed. The hybrid white OLED is a structure in which blue fluorescence is mixed with green/red phosphorescence to obtain white light emission, and the greatest possible recombination of holes and electrons may be performed in a blue fluorescent layer, and the greatest possible movement of triplet excitons formed in the recombination layer to the phosphorescent layer may take place using energy transfer to obtain green or red phosphorescent light emission. As a result, light emission efficiency is improved. Yiru Sun and co-researchers disclosed the fabrication of a hybrid white OLED having a ITO/NPB/CBP:BCzVBi/CBP/CPB:PQIr/CBP:Irppy3/CBP/CBP:BCzVBi/BPhen/LiF/Al structure to show a high-efficiency device having an external quantum efficiency of 10% or higher in Nature, Vol. 440, (2006), No. 13, pp 908-912.

In the hybrid white OLED, holes and electrons are intensively recombined at two interfaces between NPB and DBP, and between CBP and BPhen, and excitons that are generated at a fluorescent emission layer by inserting a phosphorescent emission layer therebetween are transferred to the phosphorescent emission layer at the maximum, so that phosphorescent light emission is obtained to improve light emission efficiency.

However, when the recombination layers are mainly fabricated at the two places, since holes and electrons are recombined between the recombination layers to some extent, phosphorescent light resulting from direct recombination other than energy transfer is likely to be emitted. As a result, a loss of light emission may be generated.

### DISCLOSURE OF INVENTION

### Technical Problem

The present invention is directed to a hybrid white organic light emitting diode (OLED), in which a charge recombination region is restricted to a part of a fluorescent emission layer, so that fluorescent light emission efficiency is enhanced.

The present invention is also directed to a hybrid white OLED, in which both singlet excitons and triplet excitons generated in a fluorescent emission layer are used to obtain high-efficiency white light emission.

### Technical Solution

One aspect of the present invention provides a hybrid white organic light emitting diode (OLED) including: a first electrode formed on a substrate; a hole injection layer and a hole transport layer, which are sequentially formed on the first electrode; a fluorescent emission layer formed on the hole transport layer and including a dopant and a host; an electron transport layer formed on the fluorescent emission layer and restricting a charge recombination region to a part of the fluorescent emission layer; an auxiliary emission layer spaced apart from the charge recombination region by a predetermined distance and having a phosphorescent light emitting material as a dopant; and an electron injection layer and a second electrode, which are sequentially formed on the electron transport layer.

Another aspect of the present invention provides a hybrid white OLED including: a first electrode formed on a substrate; a hole injection layer and a hole transport layer, which are sequentially formed on the first electrode; an auxiliary emission layer spaced apart from a charge recombination region by a predetermined distance and formed using a phosphorescent light emitting material as a dopant; a fluorescent emission layer formed on the hole transport layer and including a dopant and a host; an electron transport layer formed on the fluorescent emission layer; and an electron injection layer and a second electrode, which are sequentially formed on the electron transport layer, wherein the charge recombination region is restricted to a part of the fluorescent emission layer by the hole transport layer.

Still another aspect of the present invention provides a method of fabricating a hybrid white OLED including: sequentially forming a first electrode, a hole injection layer, and a hole transport layer on a substrate; forming a fluorescent emission layer formed of a host and a dopant on the hole transport layer; forming an electron transport layer on the fluorescent emission layer using a material having a higher HOMO level difference with the host of the fluorescent emission layer than a HOMO level difference between the host of the fluorescent emission layer and the hole transport layer; forming an auxiliary emission layer to be spaced apart from a charge recombination region using a phosphorescent light emitting material as a dopant; and sequentially forming an electron injection layer and a second electrode on the electron transport layer.

Yet another aspect of the present invention provides a method of fabricating a hybrid white OLED including: sequentially forming a first electrode, a hole injection layer, and a hole transport layer on a substrate; forming an auxiliary emission layer to be spaced apart from a charge recombination region using a phosphorescent light emitting material as a dopant; forming a fluorescent emission layer formed of a host and a dopant on the hole transport layer; forming an electron transport layer on the fluorescent emission layer; and sequentially forming an electron injection layer and a second electrode on the electron transport layer, wherein the hole transport layer is formed of a material having a higher LUMO level difference with the host of the fluorescent emission layer than a LUMO level difference between the host of the fluorescent emission layer and the electron transport layer.

The fluorescent emission layer may include triplet excitons that move to the auxiliary emission layer through energy transfer and emit different phosphorescent light from the fluorescent emission layer. Also, the fluorescent emission layer may be formed by doping a blue or green fluorescent dopant, respectively or simultaneously, at a doping concentration of 0.1 wt % to 50 wt %.

In addition, the auxiliary emission layer may be formed in one of the hole transport layer, the fluorescent emission layer and the electron transport layer spaced apart from the charge recombination region by a predetermined distance, and may be formed by doping a green or red phosphorescent light emitting material as a dopant at a doping concentration of 0.1 wt % to 50 wt %.

### ADVANTAGEOUS EFFECTS

According to the present invention, a HOMO level difference between a fluorescent emission layer and an electron transport layer in an organic light emitting diode (OLED) is higher than that between the other layers or a LUMO level difference between a fluorescent emission layer and a hole transport layer is higher than a LUMO level difference between the other layers, so that a recombination region is restricted to a part of an emission layer to obtain high-efficiency fluorescent light emission.

In addition, according to the present invention, triplet excitons that are not used in a fluorescent emission layer are transferred to an auxiliary emission layer formed to be spaced apart from a recombination region by a predetermined distance to emit light in a different color from the fluorescent emission layer, so that both singlet and triplet excitons generated in the OLED are used to obtain high-efficiency white light emission.

### BRIEF DESCRIPTION OF THE DRAWINGS

FIGS. 1A to 1C illustrate a stacked structure of a hybrid white organic light emitting diode (OLED) according to a first exemplary embodiment of the present invention.

FIG. 2A illustrates a stacked structure of a hybrid two-wavelength white OLED according to a second exemplary embodiment of the present invention, and FIG. 2B is a graph illustrating light emitting characteristics of the hybrid two-wavelength white OLED illustrated in FIG. 2A.

FIG. 3A illustrates a stacked structure of a hybrid three-wavelength white OLED according to a third exemplary embodiment of the present invention, and FIG. 3B is a graph illustrating light emitting characteristics of the hybrid three-wavelength white OLED illustrated in FIG. 3A.

### MODE FOR THE INVENTION

Hereinafter, exemplary embodiments of the present invention will be described in detail. However, the present invention is not limited to the exemplary embodiments disclosed below, but can be implemented in various forms. The exemplary embodiments are described to enable those of ordinary skill in the art to which the invention pertains to embody and practice the invention.

A hybrid white organic light emitting diode (OLED) and a method of fabricating the same according to the present invention will be described with reference to the accompanying drawings.

### Embodiment 1

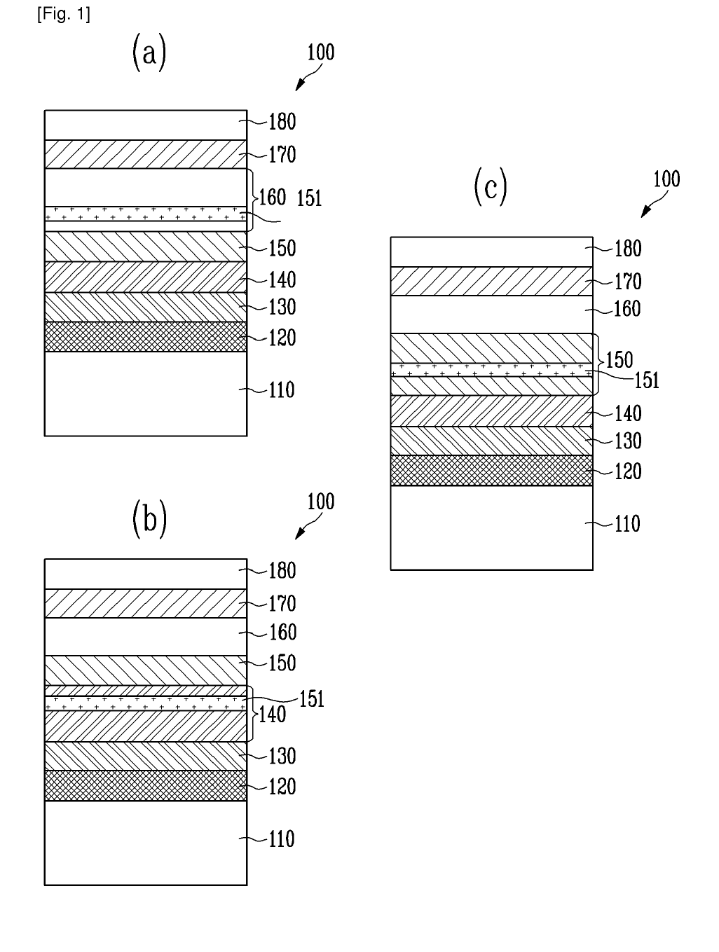

FIGS. 1A to 1C illustrate a stacked structure of a hybrid white OLED 100 according to a first exemplary embodiment of the present invention.

As illustrated in FIG. 1A, the hybrid white OLED 100 according to the present invention includes a substrate 110, a first electrode 120, a hole injection layer 130, a hole transport layer 140, a blue/green fluorescent emission layer 150 including a dopant and a host, an electron transport layer 160 formed on the fluorescent emission layer 150 and formed of a material having a higher HOMO level difference with the host of the fluorescent emission layer 150 than that between the other layers, an auxiliary emission layer 151 formed in the electron transport layer 160 and including a dopant and a host, which receive energy from triplet excitons of the fluorescent emission layer 150 and emit light, an electron injection layer 170 and a second electrode 180.

As described above, the host of the fluorescent emission layer 150 and the electron transport layer 160 has a higher HOMO level difference than that between the other layers, and thus a recombination region may be restricted to the fluorescent emission layer 150 close to the electron transport layer 160.

Also, triplet excitons that are not used in the fluorescent emission layer 150 may be changed into a phosphorescent dopant in the auxiliary emission layer 151 in the electron transport layer 160 through energy transfer, so that green/red triplet light emission can be obtained.

Here, as illustrated in FIGS. 1B and 1C, the auxiliary emission layer 151 may be formed in the hole transport layer 140 or in the fluorescent emission layer 150.

Meanwhile, a LUMO level difference between the host of the fluorescent emission layer 150 and the hole transport layer 140 may be higher than that between the other layers, so that a charge recombination region may be restricted to the fluorescent emission layer 150 close to the hole transport layer 140.

That is, in the hybrid white OLED 100 according to the present invention, the recombination region is efficiently restricted to one place of the fluorescent emission layer 150, so that phosphorescent light is emitted by the recombination of charge, and triplet excitons that are not used in the fluorescent emission layer 150 are transferred to the auxiliary emission layer 151 formed to be spaced apart from the recombination region to emit different light from the fluorescent emission layer 150, so that both singlet and triplet excitons formed in an OLED are used to obtain very high-efficiency white light emission.

Meanwhile, a HOMO level difference and a LUMO level difference between the hole transport layer 130 adjacent to the host of the fluorescent emission layer 150 and the electron transport layer 160 are adjusted, so that the fluorescent emission layer 150 can have a plurality of recombination regions therein.

That is, each layer is formed to include elements such that both a HOMO level difference between the hole transport layer 130 and the fluorescent emission layer 150 and a LUMO level difference between the electron transport layer 160 and the fluorescent emission layer 150 are high, and a plurality of recombination regions are formed in the fluorescent emission layer 150.

Specifically, a mixed material of the hole transport layer 130 and the electron transport layer 160, which have high HOMO and LUMO level differences, may be used as the host of the fluorescent emission layer 150.

For example, TcTa (HOMO 5.7 eV, LUMO 2.4 eV) may be mixed with Balq (HOMO 6.5 eV, LUMO 2.9 eV) to form the fluorescent emission layer 150, and when a hole meets the electron transport layer 160 while moving along HOMO of TcTa, it meets a high barrier to form a recombination region. In addition, when an electron meets the hole transport layer 130 while moving along LUMO of Balq, it meets a high barrier to form a recombination region.

Furthermore, a material having a high LUMO level difference with the hole transport layer 130 and having a high HOMO level difference with the electron transport layer 160 is selected to be used as the host of the fluorescent emission layer 150, so that the recombination region can be restricted to a region close to the hole transport layer 130 and to a region close to the electron transport layer 160 in the fluorescent emission layer 150.

In this case that the device having the fluorescent emission layer consisted of a plurality of recombination regions, the phosphorescent light emission layer using the triplet excitons at the fluorescent emission layer may be formed in the hole transport layer or the electron transport layer.

### Embodiment 2

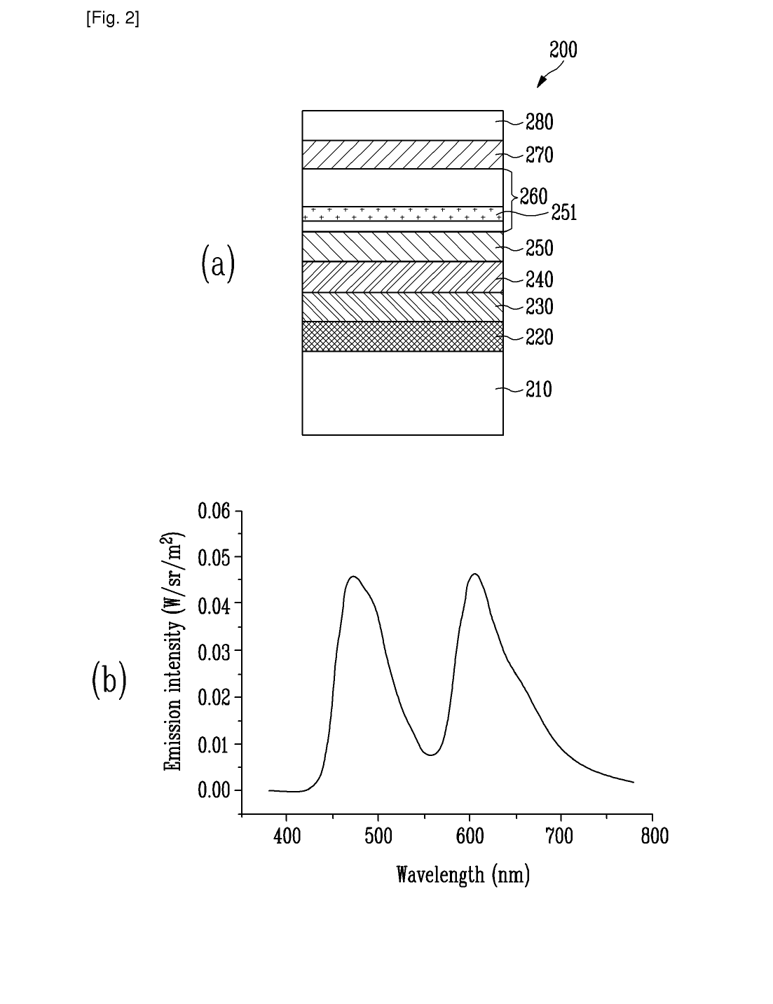

FIG. 2A illustrates a stacked structure of a hybrid two-wavelength white OLED 200 according to a second exemplary embodiment of the present invention, and FIG. 2B is a graph illustrating light emitting characteristics of the hybrid two-wavelength white OLED illustrated in FIG. 2A.

Referring to FIG. 2A, the hybrid two-wavelength white OLED 200 according to the present invention includes a substrate 210, a first electrode 220, a hole injection layer 230, a hole transport layer 240, a blue fluorescent emission layer 250, an electron transport layer 260, a red auxiliary emission layer 251, an electron injection layer 270, and a second electrode 280.

In order to fabricate the hybrid two-wavelength white OLED 200 illustrated in FIG. 2A, first, the substrate 210 is prepared. The substrate 210 may be formed of glass having transparency, quartz, or a flexible panel (e.g., plastic, and a metal thin film), and the first electrode 220 is formed on the substrate 210. The first electrode 220 may be formed of various electrode materials (a transparent material, and a metal electrode) depending on the light emission type (top, bottom, and both light emission), and a conductive metal oxide (e.g., ITO, IZO, ITZO) may be used as the electrode material having transparency.

After the first electrode 220 is formed, the hole injection layer (HIL) 230 facilitating the injection of the hole from the first electrode 220 is formed on the first electrode 220. Afterwards, the hole transport layer (HTL) 240 facilitating the transportation of the hole is formed on the HIL 230. In the present exemplary embodiment, a-NPB formed to a thickness of 40 nm was used as the HIL and the HTL.

Then, the blue fluorescent emission layer 250 is formed on the HTL 240. Here, the blue fluorescent emission layer 250 consists of a host and a dopant, the concentration of the dopant is 0.1 wt % to 50 wt %, and the deposition thickness of the blue fluorescent emission layer 250 is 0.1 to 100 nm. In the present exemplary embodiment, the blue fluorescent emission layer 250 was a thin film formed of a host and a blue fluorescent dopant formed to a thickness of 10 nm, TcTa was used as the host material, and 15% of BCzVBi as the blue fluorescent dopant was doped.

Afterwards, the electron transport layer 260 is formed on the blue fluorescent emission layer 250. Here, materials constituting the electron transport layer 260 are selected so that a HOMO level difference between the host of the blue fluorescent emission layer 250 and the electron transport layer 260 is higher than that between the other layers, and in the present exemplary embodiment, BAlq formed to a thickness of 50 nm was used as the electron transport layer 260.

Describing in more detail, TcTa used as the host of the blue fluorescent emission layer 250 has a HOMO energy of 5.9 eV, BAlq used as the electron transport layer 260 has a HOMO energy of 6.5 eV, and a-NPB used as the HTL 240 has a HOMO energy of 5.4 eV. Therefore, the host of the blue fluorescent emission layer 250 and the electron transport layer 260 has a HOMO level difference of 0.6 eV that is 0.1 eV higher than that between the host of the blue fluorescent emission layer 250 and the HTL 240.

As described above, when a HOMO level difference between the host of the blue fluorescent emission layer 250 and electron transport layer 260 is higher than that between the other layers, holes of the HTL 240 do not easily transfer to the electron transport layer 260, and thus the recombination region may be defined to the blue fluorescent emission layer 250 close to the electron transport layer 260.

Meanwhile, the red auxiliary emission layer 251 is formed in the electron transport layer 260, and is formed to be spaced apart from the blue fluorescent emission layer 250 so that only triplet excitons out of singlet excitons and the triplet excitons of the blue fluorescent emission layer 250 can move to the red auxiliary emission layer 251 through energy transfer. In the present exemplary embodiment, the red auxiliary emission layer 251 was formed to a thickness of 5 nm in the electron transport layer 260 spaced apart from the blue fluorescent emission layer 250 by a distance of 5 nm. Further, a phosphorescent material emitting green or red light was used as a dopant of the red auxiliary emission layer 251, and in the present exemplary embodiment, Irpiq was used.

Next, after the electron injection layer 270 is formed on the electron transport layer 260 using 1 nm LiF, the second electrode 280 is formed on the electron injection layer 270. Here, the second electrode 280 may be formed of various conductive materials depending on the light emission type just as in the first electrode 220.

Table 1 represents device characteristics of the hybrid two-wavelength white OLED 200, and as can be known from Table 1, the hybrid two-wavelength white OLED 200 of the present exemplary embodiment exhibits very high-efficiency light emission.

TABLE 1

| | | | Efficiency |
|---|---|---|---|
| Current (mA/cm²) | Color Coordinates | Brightness (cd/m²) | (cd/A) |
| 1 | | 250 | 25 |
| 10 | 0.37, 0.31 | 1700 | 17 |
| 100 | | 12000 | 12 |

Also, as illustrated in FIG. 2B, as a result of measuring emission intensity (EL intensity; a.u.) that is shown when a current of 10 mA/cm² is applied between the first electrode 220 and the second electrode 280 at room temperature by a spectrometer (minolta CS 1000), the hybrid white OLED 200 of the present exemplary embodiment exhibits very high-efficiency two-wavelength light emission.

### Embodiment 3

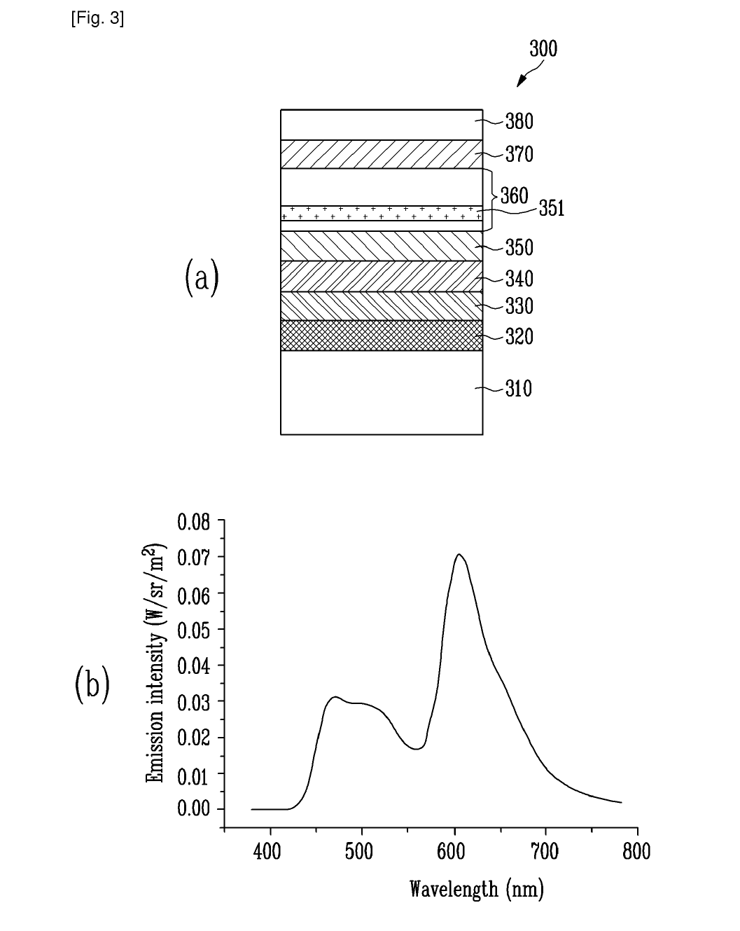

FIG. 3A illustrates a stacked structure of a hybrid three-wavelength white OLED 300 according to a third exemplary embodiment of the present invention, and FIG. 3B is a graph illustrating light emitting characteristics of the hybrid three-wavelength white OLED 300 illustrated in FIG. 3A.

Referring to FIG. 3A, the hybrid three-wavelength white OLED 300 according to the present invention includes a substrate 310, a first electrode 320, a hole injection layer 330, a hole transport layer 340, a blue/green fluorescent emission layer 350, an electron transport layer 360, a red auxiliary emission layer 351, an electron injection layer 370, and a second electrode 380.

In order to fabricate the hybrid three-wavelength white OLED 300 illustrated in FIG. 3A, first, the substrate 310 is prepared. The substrate 310 may be formed of glass having transparency, quartz, or a flexible panel (e.g., plastic, and a metal thin film), and the first electrode 320 is formed on the substrate 310. The first electrode 320 may be formed of various electrode materials (a transparent electrode, a metal electrode) depending on the light emission type (top, bottom, and both light emission), and a conductive metal oxide (e.g., ITO, IZO, ITZO) may be used as the electrode material having transparency.

After the first electrode 320 is formed, the hole injection layer (HIL) 330 facilitating the injection of the hole from the first electrode 320 is formed on the first electrode 320. Afterwards, the hole transport layer (HTL) 340 facilitating the transportation of the hole is formed on the HIL 330. In the present exemplary embodiment, a-NPB formed to a thickness of 40 nm was used as the HIL and the HTL.

Then, the blue/green fluorescent emission layer 350 is formed on the HTL 340. Here, the blue/green fluorescent emission layer 350 consists of a host and a blue/green dopant, the concentration of the blue/green dopant is 0.1 wt % to 50 wt %, and the deposition thickness of the blue/green fluorescent emission layer 350 is 0.1 to 100 nm.

In the present exemplary embodiment, the blue/green fluorescent emission layer 350 was a thin film formed of a host and a blue/green fluorescent dopant and formed to a thickness of 10 nm, TcTa was used as the host material, 15% of BCzVBi as the blue fluorescent dopant was doped, and 0.5% of C545T as the green fluorescent dopant was doped.

Afterwards, the electron transport layer 360 is formed on the blue/green fluorescent emission layer 350. Here, materials constituting the electron transport layer 360 are selected so that a HOMO level difference between the host of the blue/green fluorescent emission layer 350 and the electron transport layer 360 is higher than that between the other layers.

As described above, when a HOMO level difference between the host of the blue/green fluorescent emission layer 350 and the electron transport layer 360 is higher than that between the other layers, holes of the HTL 340 do not easily transfer to the electron transport layer 360, and thus the recombination region may be defined to the blue/green fluorescent emission layer 350 close to the electron transport layer 360. BAlq formed to a thickness of 50 nm was used as the electron transport layer 360 in the present exemplary embodiment.

Meanwhile, the red auxiliary emission layer 351 is formed in the electron transport layer 360, and is formed to be spaced apart from the blue/green fluorescent emission layer 350 so that only triplet excitons out of singlet excitons and the triplet excitons of the blue/green fluorescent emission layer 350 can move to the red auxiliary emission layer 351 through energy transfer.

In the present exemplary embodiment, the red auxiliary emission layer 351 was formed to a thickness of 5 nm in the electron transport layer 360 spaced apart from the blue fluorescent emission layer 350 by a distance of 5 nm. Further, a phosphorescent material emitting green or red light was used as a dopant of the red auxiliary emission layer 351, and in the present exemplary embodiment, Irpiq was used.

Next, after the electron injection layer 370 is formed on the electron transport layer 360 using 1 nm LiF, the second electrode 380 is formed on the electron injection layer 370. Here, the second electrode 380 may be formed of various conductive materials depending on the light emission type just as in the first electrode 320.

Table 2 represents device characteristics of the hybrid three-wavelength white OLED 300, and as can be known from Table 2, the hybrid three-wavelength white OLED 300 of the present exemplary embodiment exhibits three-wavelength white light and very high-efficiency light emission.

TABLE 2

| | | | Efficiency |
|---|---|---|---|
| Current (mA/cm²) | Color Coordinates | Brightness (cd/m²) | (cd/A) |
| 1 | | 370 | 37 |
| 10 | 0.43, 0.36 | 2600 | 26 |
| 100 | | 16000 | 16 |

Also, as illustrated in FIG. 3B, as a result of measuring emission intensity (EL intensity; a.u.) that is shown when a current of 10 mA/cm² is applied between the first electrode 320 and the second electrode 380 at room temperature by a spectrometer (minolta CS 1000), the hybrid three-wavelength white OLED 300 of the present exemplary embodiment exhibits very high-efficiency three-wavelength light emission.

While the invention has been shown and described with reference to certain exemplary embodiments thereof, it will be understood by those skilled in the art that various changes in form and details may be made therein without departing from the spirit and scope of the invention as defined by the appended claims.

1. A hybrid white organic light emitting diode (OLED), comprising:
a first electrode formed on a substrate;
a hole injection layer and a hole transport layer, which are sequentially formed on the first electrode;
a fluorescent emission layer formed on the hole transport layer and including a dopant and a host;
an electron transport layer formed on the fluorescent emission layer and restricting a charge recombination region to a part of the fluorescent emission layer;
an auxiliary emission layer spaced apart from the charge recombination region by a predetermined distance and having a phosphorescent light emitting material as a dopant; and
an electron injection layer and a second electrode, which are sequentially formed on the electron transport layer.

2. The hybrid white OLED of claim 1, wherein the electron transport layer is formed of a material having a higher HOMO level difference with the host of the fluorescent emission layer than a HOMO level difference between the host of the fluorescent emission layer and the hole transport layer.

3. A hybrid white OLED, comprising:
a first electrode formed on a substrate;
a hole injection layer and a hole transport layer, which are sequentially formed on the first electrode;
an auxiliary emission layer spaced apart from a charge recombination region by a predetermined distance and formed using a phosphorescent light emitting material as a dopant;
a fluorescent emission layer formed on the hole transport layer and including a dopant and a host;
an electron transport layer formed on the fluorescent emission layer; and
an electron injection layer and a second electrode, which are sequentially formed on the electron transport layer,
wherein the charge recombination region is restricted to a part of the fluorescent emission layer by the hole transport layer.

4. The hybrid white OLED of claim 3, wherein the hole transport layer is formed of a material having a higher LUMO level difference with the host of the fluorescent emission layer than a LUMO level difference between the host of the fluorescent emission layer and the electron transport layer.

5. The hybrid white OLED of claim 1, wherein the auxiliary emission layer is formed in one of the hole transport layer, the fluorescent emission layer and the electron transport layer spaced apart from the charge recombination region by a predetermined distance.

6. The hybrid white OLED of claim 1, wherein the fluorescent emission layer comprises triplet excitons that move to the auxiliary emission layer through energy transfer and emit phosphorescent light having a different color from the fluorescent emission layer by the phosphorescent light emitting material.

7. The hybrid white OLED of claim 1, wherein the auxiliary emission layer is formed using a green or red phosphorescent light emitting material as a dopant whose doping concentration is 0.1 wt % to 50 wt %.

8. The hybrid white OLED of claim 1, wherein the fluorescent emission layer includes a blue or green fluorescent dopant, respectively or simultaneously, and a doping concentration of the dopant is 0.1 wt % to 50 wt %.

9. A method of fabricating a hybrid white OLED, comprising:
sequentially forming a first electrode, a hole injection layer, and a hole transport layer on a substrate;
forming a fluorescent emission layer formed of a host and a dopant on the hole transport layer;
forming an electron transport layer on the fluorescent emission layer using a material having a higher HOMO level difference with the host of the fluorescent emission layer than a HOMO level difference between the host of the fluorescent emission layer and the hole transport layer;
forming an auxiliary emission layer to be spaced apart from a charge recombination region using a phosphorescent light emitting material as a dopant; and
sequentially forming an electron injection layer and a second electrode on the electron transport layer.

10. A method of fabricating a hybrid white OLED, comprising:
sequentially forming a first electrode, a hole injection layer, and a hole transport layer on a substrate;
forming an auxiliary emission layer to be spaced apart from a charge recombination region using a phosphorescent light emitting material as a dopant;
forming a fluorescent emission layer formed of a host and a dopant on the hole transport layer;
forming an electron transport layer on the fluorescent emission layer; and
sequentially forming an electron injection layer and a second electrode on the electron transport layer,
wherein the hole transport layer is formed of a material having a higher LUMO level difference with the host of the fluorescent emission layer than a LUMO level difference between the host of the fluorescent emission layer and the electron transport layer.

11. The method of fabricating a hybrid white OLED of claim 9, wherein the forming of the fluorescent emission layer includes doping a blue or green dopant, respectively or simultaneously, at a doping concentration of 0.1 wt % to 50 wt %.

12. The method of fabricating a hybrid white OLED of claim 9, wherein the forming of the auxiliary emission layer includes forming the auxiliary emission layer in one of the hole transport layer, the fluorescent emission layer and the electron transport layer spaced apart from the charge recombination region by a predetermined distance.

13. The method of fabricating a hybrid white OLED of claim 9, wherein the forming of the auxiliary emission layer includes doping at a doping concentration of 0.1 wt % to 50 wt % using a green or blue phosphorescent light emitting material as a dopant.

14. A hybrid white OLED, comprising:
a first electrode formed on a substrate;
a hole injection layer and a hole transport layer, which are sequentially formed on the first electrode;
a fluorescent emission layer formed on the hole transport layer, having at least one charge recombination region and including a dopant and a host;
an electron transport layer formed on the fluorescent emission layer;
an electron injection layer and a second electrode, which are sequentially formed on the electron transport layer; and
an auxiliary emission layer spaced apart from the charge recombination region by a predetermined distance and formed using a phosphorescent light emitting material as a dopant.

15. The hybrid white OLED of claim 14, wherein the host of the fluorescent emission layer is formed of a material having a high HOMO level difference with the electron transport layer and a high LUMO level difference with the hole transport layer.

16. The hybrid white OLED of claim 15, wherein the host of the fluorescent emission layer is formed by mixing an electron transport layer material with a hole transport layer material, which have high HOMO and LUMO level differences.

17. The hybrid white OLED of claim 15, wherein the auxiliary emission layer is formed in one of the hole transport layer, the fluorescent emission layer and the electron transport layer spaced apart from the charge recombination region by a predetermined distance.

18. The hybrid white OLED of claim 17, wherein the fluorescent emission layer includes triplet excitons that move to the auxiliary emission layer through energy transfer and emit phosphorescent light having a different color from the fluorescent emission layer by the phosphorescent light emitting material.
